(19) United States
(12) Patent Application Publication
(10) Pub. No.: US 2013/0193396 A1
(43) Pub. Date: Aug. 1, 2013

(54) VARIABLE RESISTIVE ELEMENT, AND NON-VOLATILE SEMICONDUCTOR MEMORY DEVICE

(71) Applicants: SHARP KABUSHIKI KAISHA, Osaka (JP); ELPIDA MEMORY, INC., Tokyo (JP)

(72) Inventors: Takashi NAKANO, Osaka (JP); Yukio TAMAI, Osaka (JP); Isamu ASANO, Tokyo (JP); Kazuo AIZAWA, Tokyo (JP)

(73) Assignees: ELPIDA MEMORY, INC., Tokyo (JP); SHARP KABUSHIKI KAISHA, Osaka (JP)

(21) Appl. No.: 13/753,770

(22) Filed: Jan. 30, 2013

(30) Foreign Application Priority Data
Jan. 30, 2012 (JP) 2012-017024

(51) Int. Cl. H01L 45/00

(52) U.S. Cl. CPC H01L 45/145
USPC 257/4

(57) ABSTRACT

A variable resistive element that performs a forming action at small current and a stable switching operation at low voltage and small current, and a low-power consumption large-capacity non-volatile semiconductor memory device including the element are realized. The element includes a variable resistor between first and second electrodes. The variable resistor includes at least two layers, which are a resistance change layer and high-oxygen layer, made of metal oxide or metal oxynitride. The high-oxygen layer is inserted between the first electrode having a work function smaller than the second electrode and the resistance change layer. The oxygen concentration of the metal oxide of the high-oxygen layer is adjusted such that the ratio of the oxygen composition ratio to the metal element to stoichiometric composition becomes larger than the ratio of the oxygen composition ratio to the metal element of the metal oxide forming the resistance change layer to stoichiometric composition.

### CROSS REFERENCE TO RELATED APPLICATION

This Nonprovisional application claims priority under 35 U.S.C. §119(a) on Patent Application No. 2012-017024 filed in Japan on Jan. 30, 2012 the entire contents of which are hereby incorporated by reference.

### BACKGROUND OF THE INVENTION

1. Field of the Invention

The present invention relates to a variable resistive element storing information based upon an electric operating characteristic in which a resistance changes due to application of electric stress, and to a non-volatile semiconductor memory device using the variable resistive element.

2. Description of the Related Art

A non-volatile memory represented by a flash memory has widely been used for a computer, communication, measuring device, automatic control device, and device for daily use in a personal life, as a high-capacity and compact information recording medium. A demand for an inexpensive and high-capacity non-volatile memory has been extremely increased. The reason of this is as follows. Specifically, the non-volatile memory is electrically rewritable, and further, data is not erased even if a power supply is turned off. From this viewpoint, it can exhibit a function as a memory card or a cellular phone that is easy to carry, or a data storage or a program storage that stores data as an initialization upon starting a device in a non-volatile manner.

However, in the flash memory, it takes time to perform an erasing action of erasing data to a logical value “0”, compared to a programming action for programming a logical value “1”. Therefore, the erasing action is performed on a block basis in order to speed up the action. However, there arises a problem that writing by random access cannot be performed during the erasing action since the erasing action is performed on a block basis.

In view of this, a novel non-volatile memory alternative to the flash memory has widely been studied in recent years. A resistance random access memory utilizing a phenomenon in which a resistance is changed by application of voltage to a metal oxide film is more advantageous than the flash memory in microfabrication limit. The resistance random access memory can also operate at low voltage, and can write data with high speed.

Therefore, research and development have actively been made in recent years (e.g., see National Publication of Japanese Translation of PCT Application No. 2002-537627, or H. Pagnia et al, “Bistable Switching in Electroformed Metal-Insulator-Metal Devices”, Phys. Stat. Sol. (a), Vol. 108, pp. 11-65, 1988, and Baek, I. G. et al, “Highly Scalable Non-volatile Resistive Memory using Simple Binary Oxide Driven by Asymmetric Unipolar Voltage Pulses”, IEDM 2004, pp. 587-590, 2004).

Since the programming and erasing actions can be performed at low voltage with high speed, the resistance random access memory using the variable resistive element having the metal oxide can write data at an optional address with high speed. The resistance random access memory can also use the data, which has conventionally been used after being temporarily loaded on a DRAM, directly from the non-volatile memory, thereby being expected to reduce power consumption and enhance usability of a mobile device.

As for programming and erasing characteristics of the variable resistive element having the metal oxide, pulses having different polarities are applied to increase (high resistance state) or decrease (low resistance state) the electric resistance of the element, in a driving method called bipolar switching. Therefore, the variable resistive element is used as a non-volatile memory by assigning a logical value to the respective resistance states as data.

As illustrated in FIG. 15, a conventional variable resistive element includes a lower electrode 103, a variable resistor 102, and an upper electrode 101, those of which are stacked in this order. It has the property of reversibly changing a resistance value by applying a voltage pulse between the upper electrode 101 and the lower electrode 103. The conventional variable resistive element extracts information, which is stored as a resistance state, by reading the resistance value that is changed according to the reversible resistance change.

A non-volatile semiconductor memory device includes a memory cell array and a peripheral circuit. The memory cell array includes a plurality of memory cells, each of which has the variable resistive element described above, wherein the memory cells are arranged in a matrix in a row direction and in a column direction respectively. The peripheral circuit controls a programming action, erasing action, and reading action of data to each memory cell in the memory cell array. Because of the difference in the components of the memory cell, there are a memory cell array (referred to as “1T1R memory cell array”) in which a memory cell includes one selection transistor T and one variable resistive element R, and a memory cell array (referred to as “1R memory cell array”) in which a memory cell includes only one variable resistive element R, as the memory cell array described above.

Examples of the metal oxides used for the variable resistor 102 in the above variable resistive element include metal oxides having a perovskite structure represented by praseodymium calcium manganese oxide Pr₁₋ₓCaₓMnO₃(PCMO), and binary metal oxides such as nickel oxide, titanium oxide, hafnium oxide, or zirconium oxide.

In particular, the use of the binary metal oxides has an advantage of easy microfabrication, and reduced cost for the manufacture, since the binary metal oxides are made of materials used in a conventional semiconductor production line.

In order to realize satisfactory resistance switching by using the binary metal oxides described above, the variable resistance element is formed to be asymmetric in which a thin film of the metal oxide is sandwiched by metal electrodes, and an interface between one of the metal electrodes at both ends and the oxide becomes an ohmic junction or a state close to the ohmic junction, while an interface between the other metal electrode and the oxide becomes a state such as a schottky junction where a gap of conductive carriers is caused. With this configuration, the resistance state of the variable resistive element is changed between the high resistance state and the low resistance state by the application of voltage pulses having different polarities. Accordingly, satisfactory bipolar switching can be realized.

C. Y. Lin, et al, “Effect of Top Electrode Material on Resistive Switching Property of ZrO2 Film Devices”, IEEE Electron Device Letter, Vol. 28, No. 5, 2007, pp. 366-368 (hereinafter referred to as Known Document 1), and S. Lee, et al, “Resistance Switching Behavior of Hafnium Oxide Films Grown by MOCVD for Non Volatile Memory Application”, Journal of Electrochemical Society, 155, (2), H92-H96, (2008) (hereinafter referred to as Known Document 2) describe respectively a variable resistive element using Pt for one electrode, and satisfactory bipolar switching is possible for zirconium oxide and hafnium oxide. In Known Document 1, the bipolar switching is realized by sandwiching the zirconium oxide, which is deposited by sputtering, between a Pt electrode and a Ti electrode. On the other hand, in Known Document 2, the bipolar switching is realized by sandwiching the hafnium oxide, which is deposited by MOCVD, between a Pt electrode and an Au electrode, although the number of times of writing is one.

International Publication No. WO2010/004705 describes that a stacked structure of at least two oxide hafnium (HfO_{X}) layers, each having a different oxygen concentration, is sandwiched between electrodes, wherein one of two layers is the oxide hafnium layer (0.9≦X≦1.6) having a large number of oxygen defects, and the other one is the oxide hafnium layer (1.8≦X≦2.0) having a small amount of oxygen defects. This publication also describes that the resistance of the element decreases due to the application of a positive voltage pulse to the electrode with which the oxide hafnium layer having a large number of oxygen defects is in contact, and increases due to the application of a negative voltage pulse thereto. The resistance change is considered to be caused because oxygen is collected or diffused near an interface between the electrode and the oxide layer having a small amount of oxygen defects.

Moreover, when the metal oxide having a relatively small band gap such as titanium oxide is used as the metal oxide, an electrode having a large work function such as platinum has to be used in order to form a schottky barrier at the interface with the electrode. On the other hand, when an oxide having a large band gap such as hafnium oxide or zirconium oxide is used, a satisfactory schottky barrier can be formed by using an inexpensive material that is easy to be processed for electrodes, such as titanium nitride (TiN), whereby a satisfactory switching characteristic can be obtained, which is advantageous for integration.

In H. Y. Lee, et al, “Low Power and High Speed Bipolar Switching with A Thin Reactive Ti Buffer Layer in Robust HfO₂ Based RRAM” IEDM 2008, pp. 297-300, it is confirmed that satisfactory bipolar switching is realized in a structure having hafnium oxide that is formed by ALD (Atomic Layer Deposition) and that is sandwiched by Ti and titanium nitride.

In order to utilize the variable resistive element using the above metal oxide for an actual large-capacity semiconductor memory device, the variable resistive element has to be adapted to the leading-edge microfabrication technique. For this reason, it is necessary that the data retained in the variable resistive element can be written or read with the driving capacity of the minimum transistor manufactured by the leading-edge processing technique. Specifically, it is necessary that the resistance state of the element is changed under the condition of a low voltage of about 1 V and low current of several tens of microamperes.

In the variable resistive element using the binary metal oxide such as hafnium oxide described above, it is said that the resistance change is produced by opening and closing a conductive path (hereinafter referred to as “filament path”) generated by an oxygen defect formed in the oxide film in a filament form. The filament path is formed as a result of a soft breakdown by limiting current during a dielectric breakdown through voltage application called forming.

Accordingly, the narrower the thickness of the filament path is, the more the current required for the switching, i.e., the current necessary for opening and closing the filament path that is the cause of the resistance switching is reduced.

Generally, when voltage is applied to the variable resistive element from an external power source to carry out the forming, the lower limit of the current necessary for opening and closing the formed filament path is about 1 mA. This is because it is difficult to control the influence of current spike to a parasitic capacitance during the forming.

On the other hand, when the amount of current flowing through the variable resistive element during the forming is limited by using a microfabricated transistor close to the variable resistive element on the same chip, the current spike that charges the parasitic capacitance can drastically be reduced. Therefore, the lower limit of the current necessary for opening and closing the formed filament path can be reduced to about 10 μA to 100 μA.

On the other hand, in the variable resistive element using hafnium oxide or zirconium oxide, it is difficult to reduce the current required for the switching to be not more than about 10 μA to 100 μA only by the current control by the transistor. This is based upon the reason described below. Specifically, these metal oxides have a band gap large enough for forming a satisfactory schottky barrier even by a metal having a small work function such as TiN compared to Pt. This means that the coupling between the metal and oxygen is very strong. In order to form the filament path, a certain level of voltage and current for breaking the coupling between the metal and oxygen have to be applied to move the oxygen. However, in the metal oxide having very strong coupling between metal and oxygen, such as hafnium oxide and zirconium oxide, the amount of applied voltage and current necessary for forming the filament path is large. Therefore, it is difficult to form a small filament path, which means it is difficult to reduce the switching current.

A solid line in FIG. 16 indicates a change in a breakdown current that is a lower limit of a limited current for the forming with respect to a stoichiometric composition ratio X of oxygen to hafnium in hafnium oxide HfO_{X}. A broken line in FIG. 16 indicates a duration of the voltage pulse needed for a set operation (an operation for decreasing the resistance) through the application of the voltage pulse of 2.0 V with the current being limited to 20 μA or less.

It is found from FIG. 16 that the duration of the voltage pulse needed for the set operation is reduced by decreasing the stoichiometric composition ratio X of HfO_{X}, whereby the element can be operated with higher speed.

However, the breakdown current increases, in contrast, by decreasing the stoichiometric composition ratio X of HfO_{X}. As a result, leak current (current upon dielectric breakdown) rapidly increases. Accordingly, it is difficult to perform the forming with small current such as in nanoampere order, so that a small filament is difficult to form, which means it is difficult to perform resistance switching with low voltage and small current.

When the set operation is executed with the operating current of 20 μA or less in the example in FIG. 16, the application of the voltage pulse for about 1 μs is needed for the set operation with X being about 1.91, which means that the high-speed operation cannot be realized.

### SUMMARY OF THE INVENTION

In view of the above problems, the present invention aims to realize a variable resistive element using a metal oxide, capable of performing a forming process with low current and performing a stable switching operation with low voltage and low current, and to realize a large-capacity low-power consumption non-volatile semiconductor memory device using the variable resistive element.

A variable resistive element according to the present invention for achieving the above object is characterized by comprising:

a variable resistor, a first electrode, and a second electrode, the variable resistor being sandwiched between the first electrode and the second electrode, wherein

an electric resistance between the first and second electrodes is reversibly changed by opening and closing a filament path, formed in the variable resistor, according to an application of voltage between the first and second electrodes,

the first electrode and the second electrode are made of conductive materials having different work functions,

the work function of the second electrode is larger than the work function of the first electrode,

the variable resistor includes a plurality of layers having at least a resistance change layer and a high-oxygen layer,

the high-oxygen layer is sandwiched between the first electrode and the resistance change layer, and

a ratio of an oxygen composition ratio to stoichiometric composition of metal oxide or metal oxynitride forming the high-oxygen layer is larger than a ratio of an oxygen composition ratio to stoichiometric composition of metal oxide or metal oxynitride forming the resistance change layer.

Moreover, the variable resistive element having the above characteristic according to the present invention is preferably configured such that standard free energy of formation of oxide of the metal oxide or metal oxynitride forming the resistance change layer is smaller than standard free energy of formation of oxide of the metal oxide or metal oxynitride forming the high-oxygen layer.

Moreover, the variable resistive element having the above characteristic according to the present invention is preferably configured such that the high-oxygen layer and the resistance change layer are in contact with each other.

Moreover, the variable resistive element having the above characteristic according to the present invention is preferably configured such that the resistance change layer is made of n-type metal oxide or n-type metal oxynitride, and the high-oxygen layer is made of n-type metal oxide or n-type metal oxynitride.

Moreover, the variable resistive element having the above characteristic according to the present invention is preferably configured such that the resistance change layer or the high-oxygen layer is made of oxide or oxynitride of a material containing at least one of Hf, Ge, Zr, Ti, Ta, W, and Al.

Moreover, the variable resistive element having the above characteristic according to the present invention is preferably configured such that the resistance change layer is made of Hf oxide (HfO_{X}) or Zr oxide (ZrO_{X}), wherein the stoichiometric composition ratio X of oxygen to Hf or Zr falls within a range of 1.7≦X≦1.97.

Moreover, the variable resistive element having the above characteristic according to the present invention is preferably configured such that the first electrode is made of a conductive material having a work function smaller than 4.5 eV, and the second electrode is made of a conductive material having a work function not less than 4.5 eV.

Moreover, the variable resistive element having the above characteristic according to the present invention is preferably configured such that the first electrode includes any one of conductive materials of transition metals of Ti, Ta, Hf, and Zr.

Moreover, the variable resistive element having the above characteristic according to the present invention is preferably configured such that the second electrode includes any one of conductive materials of Ti nitride, Ti oxynitride, Ta nitride, Ta oxynitride, titanium aluminum nitride, W, WN_{X}, Ru, RuO_{X}, Ir, IrO_{X}, and ITO.

Moreover, the variable resistive element having the above characteristic according to the present invention is preferably configured such that an oxide layer or oxynitride layer of the conductive material forming the first electrode or the second electrode is formed on the first electrode or the second electrode that is in contact with the variable resistor through the oxide layer or oxynitride layer.

A non-volatile semiconductor memory device according to the present invention for achieving the above object is characterized by comprising a memory cell array including a plurality of variable resistive elements having the above characteristics according to the present invention arranged in at least one of a row direction and a column direction.

Moreover, the non-volatile semiconductor memory device having the above characteristic according to the present invention is characterized by comprising a three-dimensional memory cell array including a plurality of variable resistive elements having the above characteristics according to the present invention arranged in a row direction, in a column direction, and in a third direction perpendicular to the row direction and the column direction.

In the present invention, in the variable resistive element having the variable resistor sandwiched between the first electrode and the second electrode, the variable resistor includes at least two layers that are the resistance change layer and the high-oxygen layer, wherein the oxygen concentration is set such that the ratio of the oxygen composition ratio to the stoichiometric composition of the metal oxide or metal oxynitride forming the high-oxygen layer becomes larger than the ratio of the oxygen composition ratio to the stoichiometric composition of the metal oxide or metal oxynitride forming the resistance change layer. This structure facilitates to open and close a filament path, whereby voltage and current required for a switching operation can be reduced.

It is found from a first principle calculation that energy required to break a bond of one oxygen from hafnium oxide, which is ideally defect-free, so as to form an oxygen defect is very high such as 6.16 eV. On the other hand, it is found that oxygen can go over a potential barrier with low energy such as 1.96 eV on the shortest route in the film having the oxygen defect.

A perfect defect-free oxide is not present in nature. It has widely been known that a stoichiometric composition ratio of hafnium oxide or zirconium oxide is shifted toward the lack of oxygen in nature, and hafnium oxide or zirconium oxide is classified into an n-type metal oxide having n-type conductive property due to an oxygen defect. Accordingly, a film grown by a general process has an oxygen defect. Japanese Unexamined Patent Application Publication No. 2013-004655, which was filed by one of joint applicants of the subject application, describes that, in the case of the hafnium oxide or zirconium oxide, in particular, oxygen is easy to move, and the filament path is easy to be opened and closed, by using a film having an oxygen defect, and having a stoichiometric composition ratio X of oxygen in hafnium oxide (HfOₓ) or zirconium oxide (ZrOx) falling within the range of 1.7≦x≦1.97 (more preferably, within the range of 1.84≦X≦1.92), whereby voltage and current required for the switching operation is reduced.

Moreover, in the present invention, the oxygen ratio is made different between the resistance change layer and the high-oxygen layer in order to make the oxygen defect concentration of the resistance change layer more than the oxygen defect concentration of the high-oxygen layer. With this structure, the filament path is opened and closed in the resistance change layer in which oxygen easily moves due to a large number of oxygen defects, while the filament path is always opened in the high-oxygen layer. Accordingly, the variable resistive element that can perform a stable switching operation with low voltage and small current can be realized.

When the resistance change layer and the high-oxygen layer are made of different metal oxides, the oxygen concentration (oxygen defect concentration) is evaluated as the “ratio of the oxygen composition ratio to the stoichiometric composition) as described below.

For example, it is supposed that the resistance change layer is oxide hafnium (HfO_{X}), and the high-oxygen layer is aluminum oxide (AlO_{Y}). The hafnium oxide having the ideal stoichiometric composition ratio with no oxygen defect is HfO₂. Therefore, the ratio of the oxygen composition ratio to the stoichiometric composition of the metal oxide (HfO_{X}) forming the resistance change layer is X/2.

On the other hand, the aluminum oxide having the ideal stoichiometric composition ratio with no oxygen defect is Al₂O₃. Specifically, the composition ratio with no oxygen defect is such that 3/2 oxygen atom is present for one aluminum atom. In this case, the ratio of the oxygen composition ratio to the stoichiometric composition of the metal oxide (AlO_{Y}) forming the high-oxygen layer is 2Y/3 that is obtained by dividing Y by 3/2.

In this case, the oxygen concentration of the hafnium oxide (HfO_{X}) forming the resistance change layer and the oxygen concentration of the aluminum oxide (AlO_{Y}) forming the high-oxygen layer are adjusted to establish X/2<2Y/3. Thus, the variable resistive element that facilitates to open and close the filament path and that can perform a stable switching operation with low voltage and small current can be realized.

When the resistance change layer or the high-oxygen layer is made of metal oxynitride (e.g., HfO_{X}N_{Z}), the ratio of the oxygen composition ratio to the stoichiometric composition may be calculated with respect to the ideal stoichiometric composition ratio, which is HfO₂, not containing nitrogen atom.

The process that can easily form a film in non-equilibrium state, such as a sputtering method, is used for forming a film of the metal oxide so as to form the metal oxide film that has the oxygen composition ratio satisfying the above-mentioned condition, whereby the resistance change layer and the high-oxygen layer can be formed.

The variable resistive element is formed to have an asymmetric structure in which an interface between one of the first electrode and the second electrode and the oxide becomes an ohmic junction or a state close to the ohmic junction, while an interface between the other electrode and the oxide becomes a state such as a schottky junction where energy gap of conductive carriers is caused. With this configuration, the resistance state of the variable resistive element is changed between the high resistance state and the low resistance state by the application of voltage pulses having different polarities. The filament is opened and closed on the interface between the electrode, to which an electric field is easily applied, and which has relatively large energy gap, and the oxide. Therefore, the variable resistive element according to the present invention can be realized by the structure in which the resistance change layer is in contact with the one (here, the second electrode), having relatively a high work function, of both electrodes.

As a result, the variable resistive element can easily be driven by using a microfabricated transistor having low breakdown voltage. Consequently, the variable resistive element that can perform a stable switching operation with low voltage and small current can be realized. A high-integrated large-capacity non-volatile semiconductor memory device including the variable resistive element can easily be realized.

### BRIEF DESCRIPTION OF THE DRAWINGS

FIG. 1 is a schematic sectional view illustrating one example of a structure of a variable resistive element according to one embodiment of the present invention;

FIG. 2 is a table illustrating combinations of electrodes that can perform resistance switching, and polarities of the driving voltage in the switching in the variable resistive element according to the present invention;

FIG. 3 is a graph illustrating a relationship between a flow rate of oxygen gas added to Ar gas and a resistance value of a formed film during film formation of an hafnium oxide film by a sputtering method;

FIG. 4 is a view illustrating a cumulative frequency distribution of a resistance value in a high resistance state and a resistance value in a low resistance state after the switching operation in the variable resistive element according to the present invention;

FIG. 5 is an equivalent circuit diagram illustrating a memory cell including a transistor connected in series to the variable resistive element according to the present invention;

FIG. 6 is a view illustrating a temperature change in free energy of formation of oxide of the metal oxide;

FIG. 7 is a view illustrating a cumulative frequency distribution of a resistance value in a high resistance state and a resistance value in a low resistance state after the switching operation in the variable resistive element according to the present invention;

FIG. 8 is a circuit block diagram illustrating a schematic configuration of a non-volatile semiconductor memory device according to the present invention;

FIG. 9 is a circuit diagram illustrating a schematic configuration of a memory cell array having 1T1R structure including the variable resistive element according to the present invention;

FIG. 10 is a schematic sectional view illustrating one example of a structure of a memory cell array including the variable resistive element according to the present invention;

FIG. 11 is a perspective view illustrating one example of a structure of a memory cell array including the variable resistive element according to the present invention;

FIG. 12 is a schematic sectional view illustrating one example of a structure of a memory cell array including the variable resistive element according to the present invention;

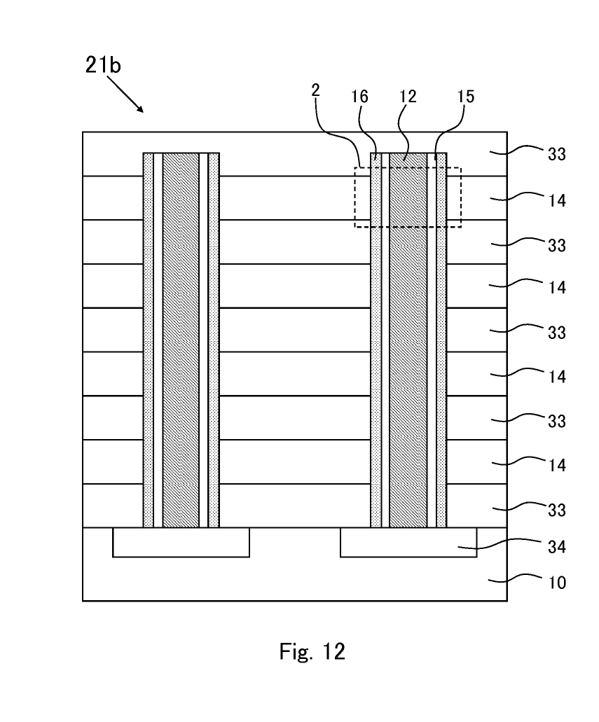

FIG. 13 is a schematic sectional view illustrating one example of a structure of a variable resistive element according to one embodiment of the present invention;

FIG. 14 is a circuit diagram illustrating a schematic configuration of a memory cell array having 1R structure including the variable resistive element according to the present invention;

FIG. 15 is a schematic sectional view illustrating one example of a structure of a conventional variable resistive element;

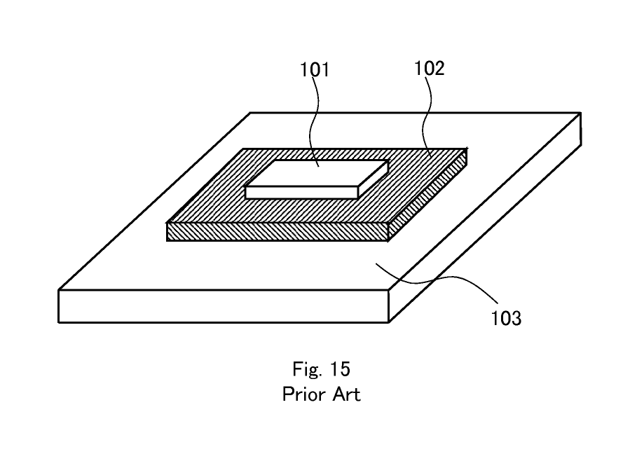

FIG. 16 is a graph illustrating a dependency of breakdown current during a forming process and a duration of a voltage pulse needed for performing a set operation (for changing a resistance state to a low resistance state), on an oxygen composition ratio X of hafnium oxide HfO_{X} forming the variable resistor.

### DESCRIPTION OF THE PREFERRED EMBODIMENTS

### First Embodiment

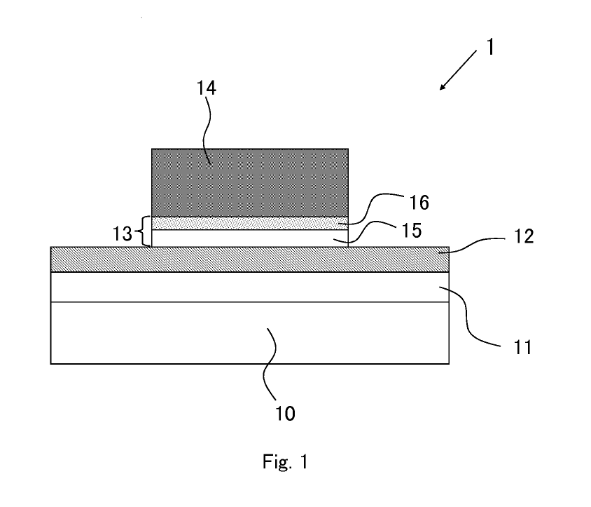

FIG. 1 is a sectional view schematically illustrating a structure of a variable resistive element 1 (hereinafter appropriately referred to as “present element 1”) according to one embodiment of the present invention.

In the drawings described below, essential parts are emphasized for the sake of convenience of description, and a dimensional ratio of each component of the element and an actual dimensional ratio do not agree with each other in some cases.

The variable resistive element 1 includes a second electrode (lower electrode) 12, a variable resistor 13, and a first electrode (upper electrode) 14, those of which are deposited and patterned in this order on an insulating film 11 formed on a substrate 10. The variable resistor 13 includes at least two layers which are a resistance change layer 15 and a high-oxygen layer 16, and each of which is made of a metal oxide film or a metal oxynitride film.

In the present embodiment, hafnium oxide (HfO_{X}) that has a large bandgap and that is an insulating layer is selected to be used for the resistance change layer 15. However, the present invention is not limited thereto. Examples of the resistance change layer 15 include metal oxides or oxynitrides, such as zirconium oxide (ZrO_{X}), titanium oxide (TiO_{X}), tantalum oxide (TaO_{X}), tungsten oxide (WO_{X}), aluminum oxide (AlO_{X}), germanium oxide (GeO_{X}), hafnium oxynitride (HfO_{X}N_{Z}), zirconium oxynitride (ZrO_{X}N_{Z}), titanium oxynitride (TiO_{X}N_{Z}), tantalum oxynitride (TaO_{X}N_{Z}), tungsten oxynitride (WO_{X}N_{Z}), aluminum oxynitride (AlO_{X}N_{Z}), or germanium oxynitride (GeO_{X}N_{Z}). These are n-type metal oxides or n-type metal oxynitrides.

In addition, when hafnium oxide (HfO_{X}) is used for the resistance change layer 15, it is preferable that its oxygen concentration x (the stoichiometric composition ratio of oxygen to hafnium) is adjusted to fall within the range of 1.7≦x≦1.97, more preferably within the range of 1.84≦x≦1.92.

The high-oxygen layer 16 is made of oxide or oxynitride of a metal same as or different from the material of the resistance change layer 15. It is configured such that the ratio of the oxygen composition ratio to the stoichiometric composition of the metal oxide or metal oxynitride in the high-oxygen layer 16 is larger than that of the resistance change layer 15. In the present embodiment, a hafnium oxide film (HfO_{X}, wherein Y>X) that is the metal oxide same as that for the resistance change layer 15 and that has the oxygen ratio larger than that of the resistance change layer 15 is used for the high-oxygen layer 16.

In order to allow the variable resistive element, which is in the initial state just after being produced, to have a state (variable resistance state) in which the resistance state can be changed between a high resistance state and a low resistance state by electric stress, it is necessary to perform a so-called forming process before the variable resistive element is used. Specifically, in the forming process, a voltage pulse, which has a voltage amplitude larger than that of a voltage pulse used for a normal writing action and has a pulse width longer than that of the same voltage pulse, is applied to the variable resistive element so as to form a current path where resistance switching occurs in the resistance change layer 15. It is known that a conductive path (filament path) formed by the forming process determines the subsequent electric property of the element.

The filament path is considered to be formed or to disappear because oxygen atom is collected or diffused by an electric field near an interface between the electrode and the variable resistor. With this phenomenon, the resistance change is considered to be caused. It is also considered that the resistance change occurs on the interface between the variable resistor and the electrode having large potential barrier and large work function. Accordingly, in the present embodiment, it is supposed that the resistance change layer 15 is in contact with the electrode (here, the second electrode 12) having a large work function, out of the first electrode 14 and the second electrode 12. In this case, the resistance change layer 15 forms a schottky junction with the electrode having a larger work function.

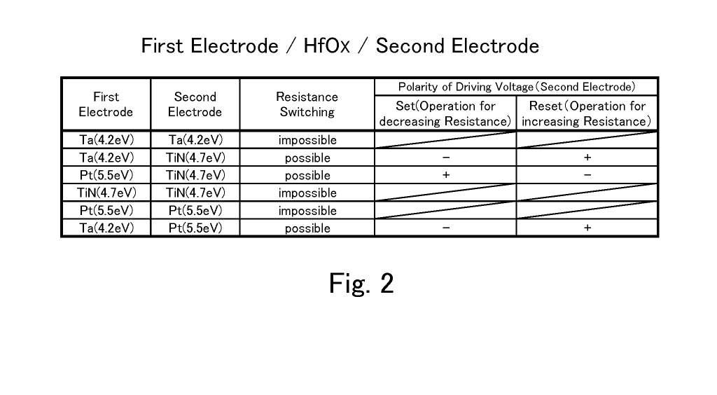

FIG. 2 shows the result of checking whether the resistance switching can be executed or not with a short pulse such as 100 ns or lower for plural variable resistive elements, each having a different combination of the first electrode 14 and the second electrode 12. FIG. 2 illustrates the result of a conventional element including only the hafnium oxide film with about 3 nm as the resistance change layer 15 without the formation of the high-oxygen layer 16. The work function of each electrode is described in parentheses.

As illustrated in FIG. 2, the resistance switching was not performed in the variable resistive elements in which the first electrode 14 and the second electrode 12 were made of the same material.

On the other hand, when the pulse that made the second electrode 12 negative with the first electrode 14 being defined as a reference was applied to the element having the second electrode 12 made of TiN or Pt and the first electrode 14 made of Ta, the resistance state was changed (set) from the high resistance state to the low resistance state. When the pulse that made the second electrode 12 positive with the first electrode 14 being defined as a reference was applied to the same element, the resistance state was changed (reset) from the low resistance state to the high resistance state, and this element could realize a high-speed switching. On the other hand, when the pulse that made the second electrode 12 positive with the first electrode 14 being defined as a reference was applied to the element having the second electrode 12 made of TiN and the first electrode 14 made of Pt, the resistance state was changed (set) from the high resistance state to the low resistance state. When the pulse that made the second electrode 12 negative with the first electrode 14 being defined as a reference was applied to the same element, the resistance state was changed (reset) from the low resistance state to the high resistance state, and this element could realize a high-speed switching.

This result shows that the high-speed switching can be realized when the material for the first electrode 14 and the material for the second electrode 12 are different from each other. From this result, it is also considered that the operating interface mainly functioning as the resistance memory is different, since polarity of the operating voltage is reversed between the case where the first electrode 14 is made of Ta and the case where the first electrode 14 is made of Pt, when the second electrode 12 is made of TiN.

In other words, the result described above shows that the resistance change occurs on the interface with the electrode having a larger work function. FIG. 2 illustrates the results of the conventional variable resistive element having no high-oxygen layer 16. However, in the element 1 having the high-oxygen layer 16 according to the present invention, the same result is considered to be obtained, so long as the high-oxygen layer 16 is inserted between the electrode having a smaller work function and the resistance change layer 15. Specifically, in the present element 1, when the pulse that makes the second electrode 12, having a larger work function, positive is applied, the resistance state is changed (set) from the high resistance state to the low resistance state, and when the pulse that makes the second electrode 12 negative, the resistance state is changed (reset) from the low resistance state to the high resistance state.

When the work function of the second electrode 12 is larger than the work function of the first electrode 14, it is preferable that the material of the first electrode 14 is selected from conductive materials having a work function smaller than 4.5 eV, while the material of the second electrode 12 is selected from conductive materials having a work function equal to or larger than 4.5 eV. Examples of the conductive material forming the first electrode 14 include Ti (4.1 eV), Hf (3.9 eV), and Zr (4.1 eV) in addition to Ta described above (the value in each parenthesis indicates a work function of the corresponding metal). Similarly, examples of the conductive material forming the second electrode 12 include Ti oxynitride (TiO_{X}N_{Z}), Ta nitride (TaN_{Z}), Ta oxynitride (TaO_{X}N_{Z}), titanium aluminum nitride (TiAlN), W, WN_{X}, Ru, RuO_{X}, Ir, IrO_{X}, or ITO (Indium Tin Oxide) in addition to Pt and TiN described above. Among the electrode materials, the combination of Ti or Ta for the first electrode 14 and TiN for the second electrode 12 is preferable from the viewpoint of easiness in integration processing.

A method of producing the present element 1 will be described below.

Firstly, a silicon oxide film with a thickness of 200 nm is formed on a monocrystalline silicon substrate 10 as an insulation film 11 by thermal oxidation method.

Then, a titanium nitride film with a thickness of 100 nm is formed on the silicon oxide film 11 as the material for the second electrode 12 by a sputtering process. Examples of the material for the second electrode may include, in addition to titanium nitride (TiN: 4.7 eV) or titanium oxynitride, tantalum nitride (TaN_{X}:4.05-5.4 eV), tantalum oxynitride, titanium aluminum nitride, W (4.5 eV), tungsten nitride WN_{X} (4.6-5.0 eV), Ru (4.68 eV), RuO_{X} (5.0-5.1 eV), Ir (5.35 eV), IrO_{X} (4.2-5.2 eV), or ITO (4.5-4.8 eV), those of which has relatively a large work function, and is popularly used in an LSI manufacturing process. The work function of each metal is described in parentheses.

Thereafter, a hafnium oxide film with a thickness of 2 to 5 nm (here, 3 nm) as the material for the resistance change layer 15 and a hafnium oxide film with a thickness of 2 to 5 nm (here, 3 nm) as the material for the high-oxygen layer 16 are continuously formed on the titanium nitride film 12, for example, by a sputtering process. In this case, the oxygen defect concentration of the high-oxygen layer 16 is controlled to be lower than the oxygen defect concentration of the resistance change layer 15 by controlling the sputtering formation ambient.

Thereafter, a tantalum film with a thickness of 150 nm is formed as the material of the first electrode 14 on the high-oxygen layer 16 by the sputtering process, for example. Finally, a pattern by a photoresist process is formed, and an element region with 5 μm×5 μm is formed by dry etching as illustrated in FIG. 1, for example. Thus, the present element 1 is formed.

During the manufacturing method described above, the metal oxide films serving as the resistance change layer 15 and the high-oxygen layer 16 are formed by reactive sputtering in which the metal forming the metal oxide films is used as a target, and the amount of oxygen to be added in the film-formation ambient is intentionally increased. With this, the film having a small amount of oxygen defects can be formed.

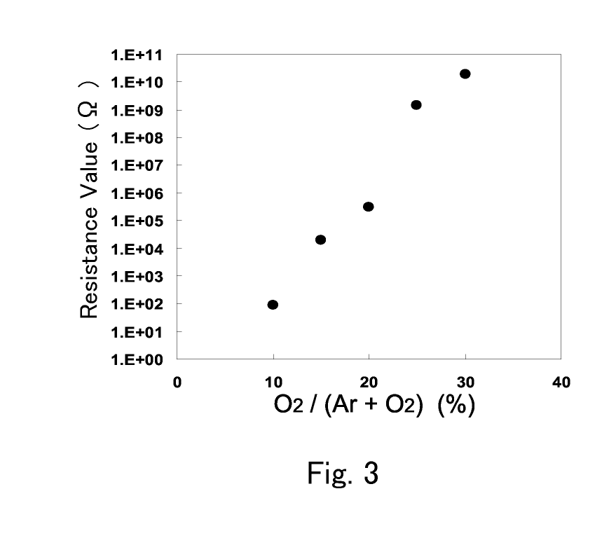

FIG. 3 illustrates the relationship between the oxygen addition amount (the ratio of oxygen partial pressure to total pressure with argon being used as diluted gas) in the film-formation ambient and the resistance value in the formation of the hafnium oxide film according to the reactive sputtering in which hafnium metal is used as a target. FIG. 3 illustrates the result in which the thickness of the metal oxide layer is 5 nm, and the area of the element region is 50 μm×50 μm. The resistance value greatly reduces by decreasing the oxygen addition amount. This is because the oxygen defect increases.

In order to stack films, each having a different oxygen defect concentration, the respective films may successively be formed with the oxygen addition amount being changed. For example, when titanium nitride is used as the second electrode 12, and tantalum is used as the first electrode 14, the respective films are formed in the order of the titanium nitride film, the hafnium oxide film with oxygen addition amount of 8%, the hafnium oxide film with oxygen addition amount of 20%, and the tantalum film. Then, the formed films are processed by photolithography and etching, whereby the variable resistive element 1 is formed. In this case, the hafnium oxide HfO_{X} film (X=1.85) formed first with the oxygen addition amount of 8% becomes the resistance change layer 15, while the hafnium oxide HfO_{Y} film (y=2.0) formed later with a small amount of oxygen defects becomes the high-oxygen layer 16.

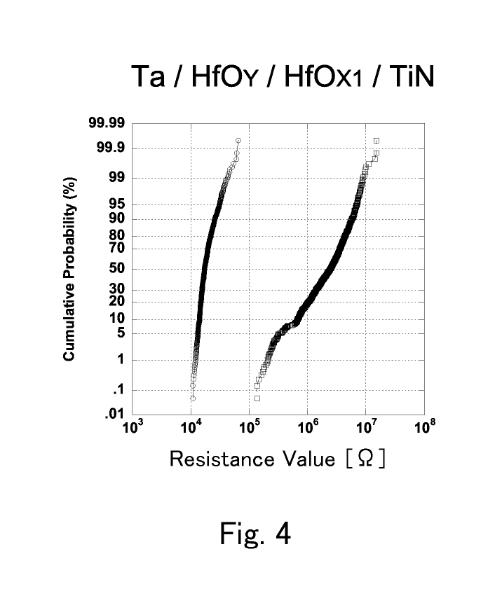

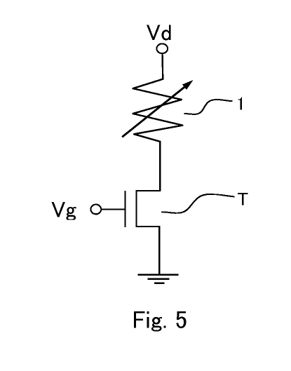

FIG. 4 illustrates a cumulative frequency distribution of a resistance value after the set operation and a resistance value after the reset operation after the 1000 bits of elements 1 according to the present invention, each of which has the hafnium oxide HfO_{X1} film (X1=1.85) formed by the manufacturing method described above as the resistance change layer 15, underwent the switching operation ten times. The experiments of the resistance switching were carried out by using a memory cell illustrated in an equivalent circuit diagram in FIG. 5 and having a transistor T connected in series, and voltage pulse Vd was applied from the present element 1.

In this case, the forming operation for forming the filament path first, and the set operation of changing the resistance state from the high resistance state to the low resistance state were each performed by applying voltage Vg to a gate of the transistor T so as to limit the current flowing through the variable resistive element, as shown in FIG. 5. In the present embodiment, the drive current of the transistor T was limited to 50 μA, and the voltage pulse of +3.0 V was applied for 100 ns during the forming operation. During the set operation for changing the resistance state from the high resistance state to the low resistance state, the drive current of the transistor T was limited to 50 μA, and the voltage pulse of +2.5 V was applied for 100 ns. On the other hand, during the reset operation for changing the resistance state from the low resistance state to the high resistance state, the gate of the transistor T was fully opened without the limitation of current, and the voltage pulse of −1.7 V was applied for 20 ns. In this case, the reset current flowing through the element during the reset operation was about 200 μA.

It is found from FIG. 4 that the present element 1 realizes stable resistance switching with the state in which the set current is limited to be not more than 50 pA. The present element 1 can also realize high-speed switching of about 100 ns.

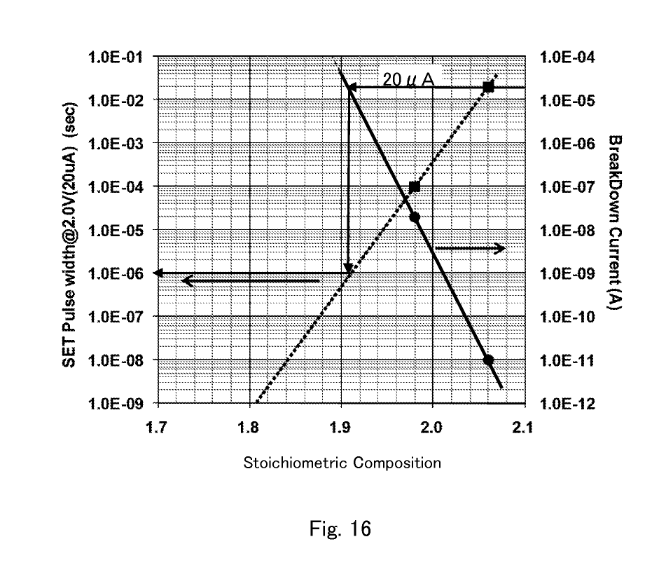

On the other hand, when the drive current of the transistor T was limited to 50 pA in the conventional variable resistive element having only the hafnium HfO_{X1} oxide film (X1=1.85) as the resistance change layer 15 without having the high-oxygen layer 16, the forming operation could not be executed. This is apparent from FIG. 16 showing that the breakdown current becomes 1 mA or higher when the stoichiometric composition ratio X of HfO_{X} is 1.85.

When the forming operation is executed with the current during the forming operation being limited to be not more than 50 μA in the conventional variable resistive element having no high-oxygen layer 16, X=1.9 or higher is needed as the oxygen concentration of the resistance change layer 15, as is understood from FIG. 16. However, in the present element 1, the forming operation is possible by limiting the current during the forming operation to be not more than 50 μA, even if the resistance change layer 15 having low oxygen concentration (X=1.85) is used, since the present element 1 includes the high-oxygen layer 16. Therefore, the element 1 can realize the resistance switching. As a result, the high-speed switching using a pulse of about 100 ns can be executed.

The present element 1 includes two hafnium oxide layers, each having a different oxygen defect concentration, wherein one of them having high oxygen defect concentration is the resistance change layer 15, while the other one having low oxygen defect concentration is the high-oxygen layer 16. However, the number of layers having different oxygen defect concentration may be three or more, and the oxygen defect concentration may continuously be changed.

### Second Embodiment

In the first embodiment described above, the present element 1 includes the resistance change layer 15 and the high-oxygen layer 16, these layers being made of the same metal oxide but having different oxygen defect concentration. However, the resistance change layer 15 and the high-oxygen layer 16 may be made of a different metal oxide. The resistance change of the variable resistive element appears since oxygen atoms are collected or diffused by the electric field near the interface between the electrode and the variable resistor. Therefore, it is more preferable that the high-oxygen layer 16 is made of a different oxide or oxynitride having free energy of formation of oxide higher than that of the oxide or oxynitride forming the resistance change layer 15. This structure facilitates the oxygen transfer from the high-oxygen layer 16 to the resistance change layer 15 during the reset operation, whereby the reset current, which is difficult to control only by the limitation of current by the transistor, can be reduced.

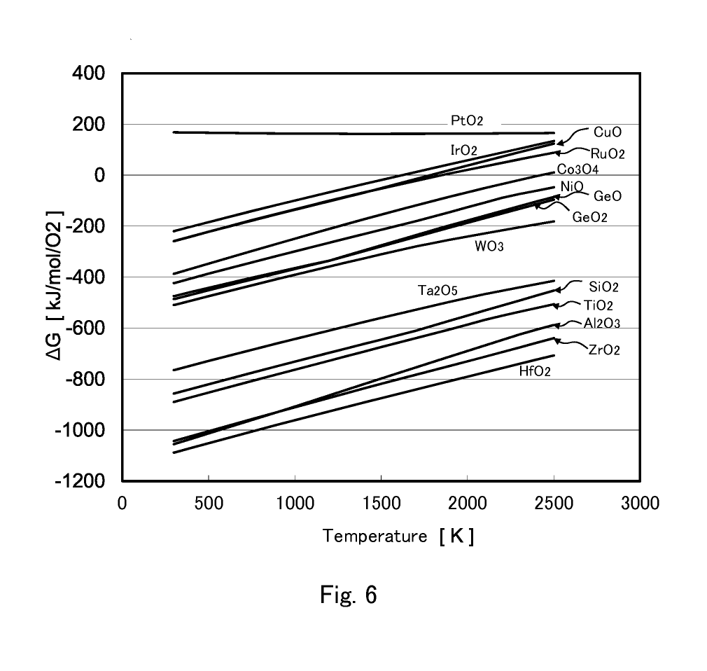

Ellingham diagram in FIG. 6 illustrates a temperature change in free energy of formation of oxide per 1 mol of oxygen molecule of the respective metal oxides. In the graphs in FIG. 6, the value of the leftmost free energy (having the lowest temperature) indicates the standard free energy of formation. It is found from FIG. 6 that hafnium oxide is a metal oxide whose standard free energy of formation is lower than that of aluminum oxide.

In the present embodiment, in the present element 1, the hafnium oxide HfO_{X} film is used as the resistance change layer 15, and an aluminum oxide AlO_{Y} film with less oxygen defect is used, instead of the hafnium oxide HfO_{Y} film with less oxygen defect, as the high-oxygen layer 16. Thus, a variable resistive element 2 is formed. This element is referred to as “the present element 2” below.

When the oxygen defect concentration is compared among metal oxides having different oxidation number, it is impossible to simply compare the oxygen defect concentration based upon the oxygen composition ratio per one metal element. It is necessary that the stoichiometric composition of the respective metal oxides is considered, and the oxygen defect concentration is compared based upon the ratio obtained by dividing the oxygen composition ratio by the oxygen composition ratio in the stoichiometric composition.

In the present embodiment, the stoichiometric composition ratio of hafnium oxide is HfO₂, and the stoichiometric composition ratio of aluminum oxide is Al₂O₃. Therefore, the value obtained by dividing the oxygen concentration X per one Hf of the HfO_{X} film forming the resistance change layer 15 by 2, and the value obtained by dividing the oxygen concentration Y per one Al of AlO_{Y} film forming the high-oxygen layer 16 by 3/2 are compared, and the oxygen concentration of the hafnium oxide (HfO_{X}) forming the resistance change layer 15 and the oxygen concentration of aluminum oxide (AlO_{Y}) forming the high-oxygen layer 16 are adjusted in order that X/2<2Y/3 is established.

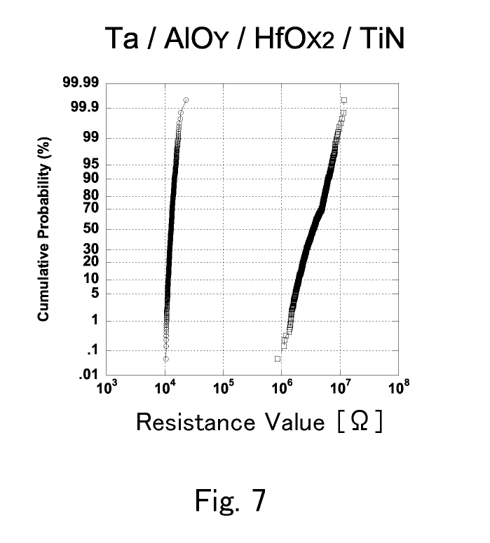

FIG. 7 illustrates a cumulative frequency distribution of a resistance value after the set operation and a resistance value after the reset operation after the 1000 bits of elements 2 according to the present invention, each of which has the hafnium oxide HfO_{X2} film (X2=1.8) as the resistance change layer 15, and the aluminum oxide (AlO_{Y}) film (Y=1.5) as the high-oxygen layer 16, underwent the switching operation ten times. As in the first embodiment, the experiments of the resistance switching were carried out by using a memory cell illustrated in the equivalent circuit diagram in FIG. 5 and having a transistor T connected in series, and voltage pulse Vd was applied from the present element 2.

In the present embodiment, the drive current of the transistor T was limited to 10 μA, and the voltage pulse of +3.2 V was applied for 100 ns during the forming operation for forming the filament path first. During the set operation for changing the element from the high resistance state to the low resistance state, the drive current of the transistor T was limited to 10 μA, and the voltage pulse of +2.5 V was applied for 100 ns. On the other hand, during the reset operation for changing the resistance state from the low resistance state to the high resistance state, the gate of the transistor T was fully opened without the limitation of current, and the voltage pulse of −1.7 V was applied for 20 ns. In this case, the reset current flowing through the element during the reset operation was about 120 μA.

It is found from FIG. 7 that the present element 2 realizes stable resistance switching with the state in which the set current is limited to be not more than 10 μA. The present element 2 can also realize high-speed switching of about 100 ns. It is also found that, compared to the variable resistive element 1 using hafnium oxide as the high-oxygen layer 16 illustrated in FIG. 4, the variation in the resistance values of the variable resistive element can be reduced.

### Third Embodiment

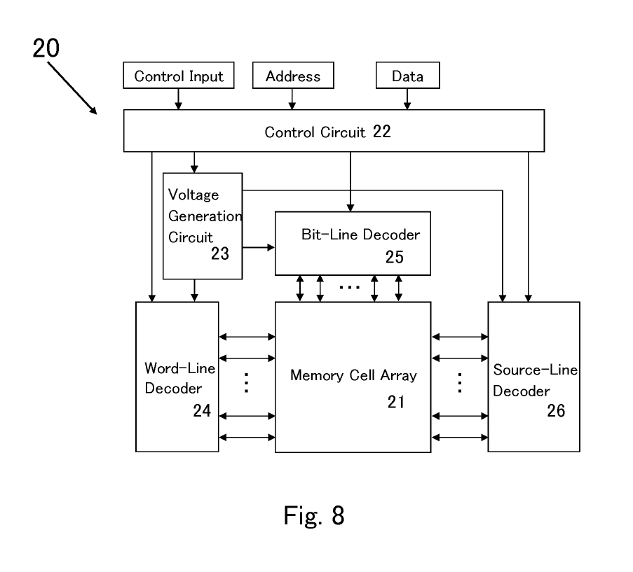

FIG. 8 illustrates a non-volatile semiconductor memory device using the present element 1 or 2 described above. FIG. 8 is a circuit block diagram illustrating a schematic configuration of a non-volatile semiconductor memory device 20 (hereinafter referred to as “present device 20” as needed) according to one embodiment of the present invention. As illustrated in FIG. 8, the present device 20 includes a memory cell array 21, a control circuit 22, a voltage generating circuit 23, a word-line decoder 24, a bit-line decoder 25, and a source-line decoder 26.

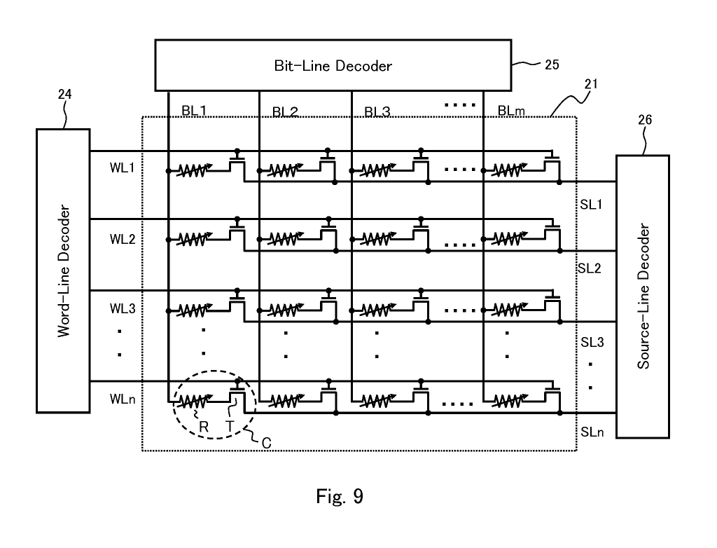

The memory cell array 21 includes a plurality of memory cells, each of which includes the variable resistive element R, in at least one of a row direction and a column direction in a matrix. The memory cells belonging to the same column are connected by a bit line extending in the column direction, and the memory cells belonging to the same row are connected by a word line extending in the row direction. The memory cell array is the one illustrated in an equivalent circuit diagram in FIG. 9, for example. The memory cell array 21 illustrated in FIG. 9 is a 1T1R memory cell array in which a unit memory cell includes a transistor T serving as a current limiting element. One electrode of the variable resistive element R is connected to one of a source or a drain of the transistor T in series to form a memory cell C. The other electrode, not connected to the transistor T, of the variable resistive element R is connected to bit lines BL1 to BLm (m is a natural number) extending in the column direction (in the vertical direction in FIG. 9), the other one of the source and the drain of the transistor T that is not connected to the variable resistive element R is connected to source lines SL1 to SLn (n is a natural number) extending in the row direction (in the lateral direction in FIG. 9), and the gate terminals of the transistors are connected to word lines WL1 to WLn extending in the row direction. Any one of selected word line voltage and non-selected word line voltage is applied through the word line, any one of selected bit line voltage and non-selected bit line voltage is applied through the bit line, and any one of selected source line voltage and non-selected source line voltage is applied through the source line, wherein these voltages are independently applied. With this process, one or a plurality of memory cells, which are targets of the action designated by an address input from the outside such as a programming action, erasing action, reading action, and forming process, can be selected.

The variable resistive element R forming the memory cell C may be either one of the present elements 1 and 2. The structure of the variable resistive element R is not particularly limited, so long as the variable resistor 13 including two layers that are the resistance change layer 15 and the high-oxygen layer 16 is sandwiched between the electrodes 11 and 12.

The control circuit 22 controls the operation of each memory, such as the programming action (an action for decreasing the resistance: set operation), the erasing action (an action for increasing the resistance: reset operation), and reading action of the memory cell array 21, and controls the forming process. Specifically, the control circuit 22 controls the word-line decoder 24, the bit-line decoder 25, and the source-line decoder 26 based upon an address signal inputted from an address line, a data input inputted from the data line, and a control input signal inputted from an a control signal line, thereby controlling the action of each memory in each memory cell and the forming process. Although not illustrated in FIG. 8, the control circuit 22 has a function of a general address buffer circuit, a data input/output buffer circuit, and a control input buffer circuit.

The voltage generating circuit 23 generates the selected word line voltage and non-selected word line voltage necessary for selecting the target memory cell during each of the programming action (an action for decreasing the resistance: set operation), the erasing action (an action for increasing the resistance: reset operation), and the reading action of the memory, and the forming process of the memory cell, and supplies the resultant to the word-line decoder 24. The voltage generating circuit 23 also generates the selected bit line voltage and non-selected bit line voltage, and supplies the resultant to the bit-line decoder 25. The voltage generating circuit 23 also generates the selected source line voltage and non-selected source line voltage, and supplies the resultant to the source-line decoder 26.

When the target memory cell is inputted to the address line to be designated during each of the programming action (an action for decreasing the resistance: set operation), the erasing action (an action for increasing the resistance: reset operation), and the reading action of the memory, and the forming process of the memory cell, the word-line decoder 24 selects the word line corresponding to the address signal inputted to the address line, and applies the selected word line voltage and the non-selected word line voltage to the selected word line and to the non-selected word line, respectively.

When the target memory cell is inputted to the address line to be designated during each of the programming action (an action for decreasing the resistance: set operation), the erasing action (an action for increasing the resistance: reset operation), and the reading action of the memory, and the forming process of the memory cell, the bit-line decoder 25 selects the bit line corresponding to the address signal inputted to the address line, and applies the selected bit line voltage and the non-selected bit line voltage to the selected bit line and to the non-selected bit line, respectively.

When the target memory cell is inputted to the address line to be designated during each of the programming action (an action for decreasing the resistance: set operation), the erasing action (an action for increasing the resistance: reset operation), and the reading action of the memory, and the forming process of the memory cell, the source-line decoder 26 selects the source line corresponding to the address signal inputted to the address line, and applies the selected source line voltage and the non-selected source line voltage to the selected source line and to the non-selected source line, respectively.

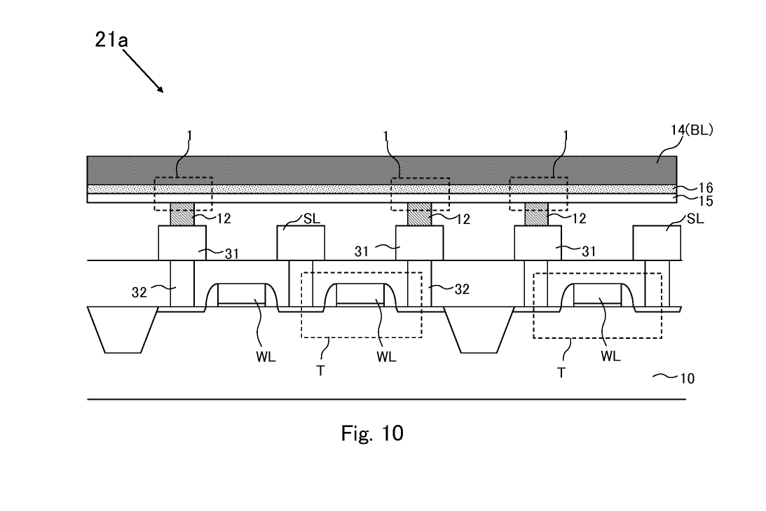

FIG. 10 is a sectional view schematically illustrating one example of a device structure of the memory cell array 21. The memory cell array 21a whose cross-section is illustrated in FIG. 10 is the 1T1R memory cell array using the present element 1 for the memory cell. In the memory cell array 21a, the first electrode 14 extends in the column direction (in the lateral direction in FIG. 10) to form the bit line BL, and the resistance change layer and the high-oxygen layer 16 similarly extend in the column direction. The contact plug that connects the transistor T formed in the lower layer via the island-like metal wiring 31 and contact plug 32 is the second electrode 12 connected to the resistance change layer 15. The variable resistive element 1 including the first electrode 14, the resistance change layer 15, the high-oxygen layer 16, and the second electrode 12 is formed on the contact region (element formation region) where the second electrode 12 is in contact with the resistance change layer 15.

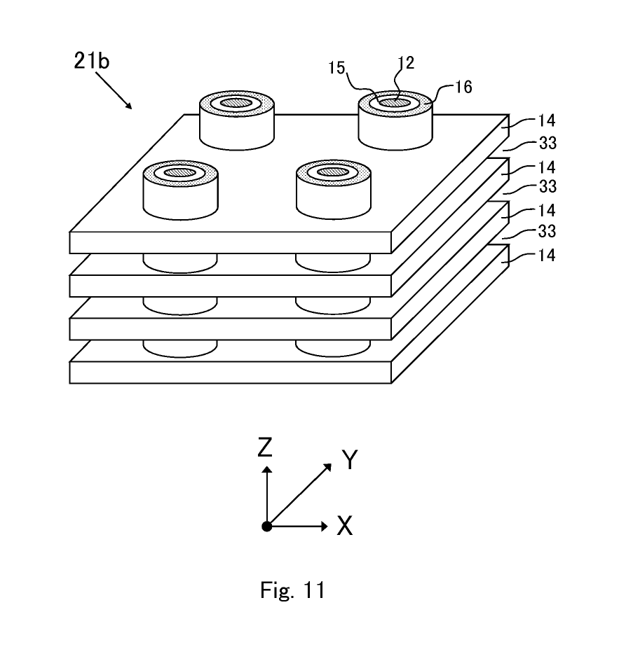

FIG. 11 is a perspective view illustrating another example of the device structure of the memory cell array 21. A memory cell array 21b illustrated in FIG. 11 is a three-dimensional memory cell array in which the present elements 2 using HfO_{X} as the resistance change layer 15 and AlO_{Y} as the high-oxygen layer 16 are arranged in X direction, Y direction, and Z direction. The memory cell array 21b is formed such that the inner peripheral sidewall of a through-hole that penetrates the stacked structure of the first electrode 14 (here, Ti) and an interlayer dielectric film 33 is covered successively by the high-oxygen layer 16 and the resistance change layer 15, and the through-hole is filled with the second electrode 12 (here, TiN).

FIG. 11 illustrates the cross-sectional structure on XZ section or YZ section including the axis of the through-hole. The second electrode 12 is connected to a diffusion area 34 forming the drain of the transistor T formed on the substrate 10. Each of the sheet-like first electrodes 14 becomes the bit line extending in the X direction and Y direction. The position of the variable resistive element in the X direction and Y direction is specified by using the transistor T, and the position of the variable resistive element in the Z direction is specified by selecting the bit line. With this, the action of the memory cell of the three-dimensionally arranged variable resistive element on any position can be executed.

The detailed circuit structure of the control circuit 22, the voltage generating circuit 23, the word-line decoder 24, the bit-line decoder 25, and the source-line decoder 26 can be realized by using a known circuit structure, and the device structure of these components can be manufactured by using a known semiconductor manufacturing technique. Therefore, the detailed circuit structure, the device structure, and the manufacturing method will not be described here.

According to the present invention, the variable resistive element includes the high-oxygen layer 16, whereby the variable resistive element that can perform a stable switching operation with low voltage and small current can be realized, and a large-capacity low-power consumption non-volatile semiconductor memory device using the variable resistive element can be realized.

### Other Embodiment

Other embodiments will be described below.

(1) Although the variable resistive element having the element structure illustrated in FIG. 1 is described as one example in the first and second embodiments described above, the present invention is not limited to the element having such a structure. The present invention is applicable to a variable resistive element having any structure, as long as the variable resistor 13 includes two layers that are the resistance change layer 15 and the high-oxygen layer 16, and the composition is adjusted such that the oxygen concentration of the high-oxygen layer 16 is higher than that of the resistance change layer 15. The present invention is not limited by the thickness or oxygen concentration of the resistance change layer 15 and the high-oxygen layer 16, or the element area.

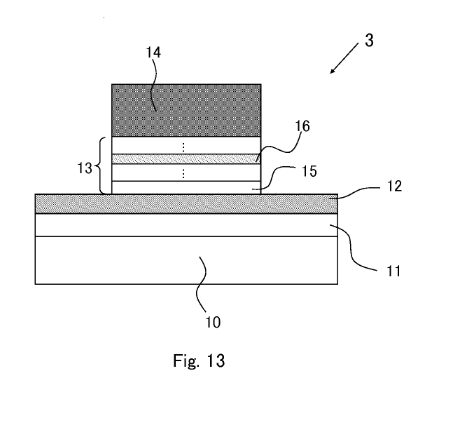

(2) The high-oxygen layer 16 is inserted between the resistance change layer and the electrode provided on the other side of the electrode with which the resistance change layer 15 is in contact. However, as illustrated in a variable resistive element 3 in FIG. 13, the high-oxygen layer 16 may be inserted as a layer other than the resistance change layer of the variable resistor including a plurality of layers.

The considered examples in which the variable resistor 13 includes a layer other than the high-oxygen layer 16 and the resistance change layer 15 include a structure in which a tunnel insulation film is inserted between the first electrode 12 and the resistance change layer 15 in order to provide a function as the non-linear current limiting element to the element, and a structure in which a buffer layer that suppresses a rapid increase in the current flowing between the electrodes of the variable resistive element upon the completion of the forming process is inserted in order to reduce the variation in filament path, formed by the forming process, among the elements. When the absolute value of the free energy of the formation of oxide of the metal forming the electrode is larger than the absolute value of the free energy of the formation of oxide of the metal oxide layer that is in contact with the electrode, a part of the electrode is oxidized, so that an oxide film or oxynitride film of the electrode is formed between the metal oxide layer and the electrode. Alternatively, when the first electrode 14 or the second electrode 12 is a lower electrode, the oxide film or oxynitride film of the lower electrode may be formed on the surface of the lower electrode after the formation of the lower electrode, due to the manufacturing process.

In the embodiments described above, the resistance change layer 15 is in contact with the second electrode 12. However, another layer may be inserted between the resistance change layer 15 and the second electrode 12. The variable resistive element according to the present invention can be realized, so long as the thickness of the tunnel insulation film, the buffer layer, or the natural oxide film inserted between the resistance change layer and the second electrode 12 is thin, and the interface with the electrode keeps the state of generating energy gap of conductive carriers, such as a schottky junction.

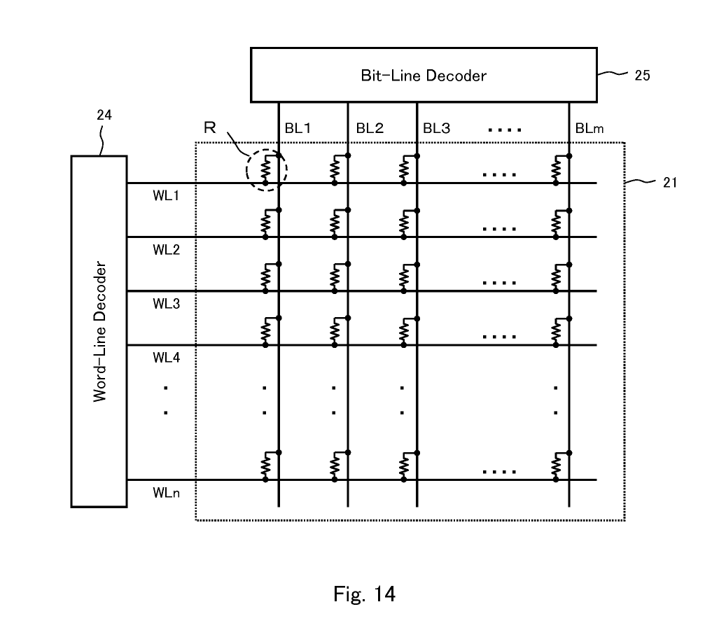

(3) In the third embodiment, the present device 20 is applicable to any memory cell array including a plurality of memory cells arranged in a matrix, so long as the variable resistive element according to the present invention including metal oxide as the resistance change layer 15 and further including the high-oxygen layer 16 is used as each of the memory cells. The present invention is not limited by the structure of the memory cell array 21 or the circuit structure of the other circuits such as the control circuit or the decoders. In particular, the memory cell array 21 may be a 1R memory cell array that does not contain a current limiting element in a unit memory cell illustrated in FIG. 14, or may be a 1D1R memory cell array including a diode, serving as a current limiting element, in a unit memory cell, in addition to the 1T1R memory cell array 21 illustrated in FIG. 9. In the 1D1R memory cell array, one end of the diode and one electrode of the variable resistive element are connected in series to form a memory cell, any one of the other end of the diode and the other electrode of the variable resistive element is connected to the bit line extending in the column direction, and the other one is connected to the word line extending in the row direction. In the 1R memory cell array, both electrodes of the variable resistive element are respectively connected to the bit line extending in the column direction and to the word line extending in the row direction.

(4) The present device 20 includes the source-line decoder 26 for selecting the source lines SL1 to SLn, wherein each source line is selected to allow the voltage necessary for the operation of the memory cell to be applied. However, the source line may be shared by all memory cells, and a ground voltage (fixed potential) may be supplied to the source line. Even in this case, the voltage necessary for the operation of the memory cell can be supplied by selecting each of bit lines BL1 to BLn through the bit-line decoder 25.

The present invention is applicable to a non-volatile semiconductor memory device, and more particularly applicable to a non-volatile semiconductor memory device including a non-volatile variable resistive element whose resistance state is changed due to application of voltage, the resistance state after the change being retained in a non-volatile manner.

Although the present invention has been described in terms of the preferred embodiment, it will be appreciated that various modifications and alternations might be made by those skilled in the art without departing from the spirit and scope of the invention. The invention should therefore be measured in terms of the claims which follow.

What is claimed is:

1. A variable resistive element comprising:
a variable resistor, a first electrode, and a second electrode, the variable resistor being sandwiched between the first electrode and the second electrode, wherein
an electric resistance between the first and second electrodes is reversibly changed by opening and closing a filament path, formed in the variable resistor, according to an application of voltage between the first and second electrodes,
the first electrode and the second electrode are made of conductive materials having different work functions,
a work function of the second electrode is larger than a work function of the first electrode,
the variable resistor includes a plurality of layers having at least a resistance change layer and a high-oxygen layer,
the high-oxygen layer is sandwiched between the first electrode and the resistance change layer, and
a ratio of an oxygen composition ratio to stoichiometric composition of metal oxide or metal oxynitride forming the high-oxygen layer is larger than a ratio of an oxygen composition ratio to stoichiometric composition of metal oxide or metal oxynitride forming the resistance change layer.

2. The variable resistive element according to claim 1, wherein
standard free energy of formation of oxide of the metal oxide or metal oxynitride forming the resistance change layer is smaller than standard free energy of formation of oxide of the metal oxide or oxynitride forming the high-oxygen layer.

3. The variable resistive element according to claim 1, wherein the high-oxygen layer and the resistance change layer are in contact with each other.

4. The variable resistive element according to claim 1, wherein
the resistance change layer is made of n-type metal oxide or n-type metal oxynitride, and the high-oxygen layer is made of n-type metal oxide or n-type metal oxynitride.

5. The variable resistive element according to claim 4, wherein
the resistance change layer or the high-oxygen layer is made of oxide or oxynitride of a material containing at least one of Hf, Ge, Zr, Ti, Ta, W, and Al.

6. The variable resistive element according to claim 5, wherein
the resistance change layer is made of Hf oxide (HfO_{X}) or Zr oxide (ZrO_{X}), wherein the stoichiometric composition ratio X of oxygen to Hf or Zr falls within a range of 1.7≦X≦1.97.

7. The variable resistive element according to claim 1, wherein
the first electrode is made of a conductive material having a work function smaller than 4.5 eV, and the second electrode is made of a conductive material having a work function not less than 4.5 eV.

8. The variable resistive element according to claim 1, wherein
the first electrode includes any one of conductive materials of transition metals of Ti, Ta, Hf, and Zr.

9. The variable resistive element according to claim 1, wherein
the second electrode includes any one of conductive materials of Ti nitride, Ti oxynitride, Ta nitride, Ta oxynitride, titanium aluminum nitride, W, WN_{X}, Ru, RuO_{X}, Ir, IrO_{X}, and ITO.

10. The variable resistive element according to claim 1, wherein
an oxide layer or oxynitride layer of the conductive material forming the first electrode or the second electrode is formed on the first electrode or the second electrode that is in contact with the variable resistor through the oxide layer or oxynitride layer.

11. A non-volatile semiconductor memory device comprising:
a memory cell array including a plurality of variable resistive elements according to claim 1 arranged in at least one of a row direction and a column direction.

12. A non-volatile semiconductor memory device comprising:
a three-dimensional memory cell array including a plurality of variable resistive elements according to claim 1 arranged in a row direction, in a column direction, and in a third direction perpendicular to the row direction and the column direction.
